(19) United States
(12) Patent Application Publication
(10) Pub. No.: US 2025/0233559 A1
(43) Pub. Date: Jul. 17, 2025

(54) AMPLIFIER CIRCUIT, TRACKER MODULE, AMPLIFYING MODULE, AND COMMUNICATION DEVICE

(71) Applicant: Murata Manufacturing Co., Ltd., Nagaokakyo-shi (JP)

(72) Inventors: Yusaku MUROYA, Nagaokakyo-shi (JP); Toshiki MATSUI, Nagaokakyo-shi (JP); Satoshi SAKURAI, Nagaokakyo-shi (JP); Hironori CHIKITA, Nagaokakyo-shi (JP); Kousuke KAWAKAMI, Nagaokakyo-shi (JP)

(73) Assignee: Murata Manufacturing Co., Ltd., Nagaokakyo-shi (JP)

(21) Appl. No.: 19/058,007

(22) Filed: Feb. 20, 2025

Related U.S. Application Data
(63) Continuation of application No. PCT/JP2023/028197, filed on Aug. 1, 2023.

(30) Foreign Application Priority Data
Sep. 20, 2022 (JP) 2022-149245

(51) Int. Cl. H03F 1/02; H03F 3/24; H04B 1/04

(52) U.S. Cl. CPC H03F 1/0233; H03F 3/245; H04B 1/04; H03F 2200/102; H03F 2200/451; H03F 2200/504; H03F 2200/507; H03F 2203/21157; H04B 2001/0408

(57) ABSTRACT

An amplifier circuit includes power amplifiers, trackers capable of outputting a variable power supply voltage, a switch connected between an output port of the tracker and an output port of the tracker, and a switch connected between the output port of the tracker and the power amplifier, and the output port of the tracker is connected to the power amplifier.

### CROSS-REFERENCE TO RELATED APPLICATIONS

This is a continuation application of PCT/JP2023/028197, filed on Aug. 1, 2023, designating the United States of America, which is based on and claims priority to Japanese Patent Application No. JP 2022-149245 filed on Sep. 20, 2022. The entire contents of the above-identified applications, including the specifications, drawings and claims, are incorporated herein by reference in their entirety.

### TECHNICAL FIELD

The present disclosure relates to an amplifier circuit, a tracker module, an amplifying module, and a communication device.

### BACKGROUND ART

Patent Document 1 discloses an amplifier circuit including a tracker circuit through which a power supply voltage is supplied based on envelope tracking and a power amplifier that supports 5th Generation (5G) and that receives the power supply voltage from the tracker circuit.

### CITATION LIST

### Patent Document

Patent Document: U.S. Patent Application Publication No. 2020/0228063, specification

### SUMMARY OF DISCLOSURE

### Technical Problem

In the amplifier circuit disclosed in Patent Document 1, the power supply voltage is supplied from the one tracker circuit to the one power amplifier. However, assuming a high power signal in a high power class is required to be output from the power amplifier, an increase in a power supply voltage (current) output from the tracker circuit leads to a decrease in the efficiency of the tracker circuit and also causes excessive load on the one tracker circuit to generate heat leading to a decrease in the efficiency of the power amplifier on occasions.

Hence, the present disclosure provides an amplifier circuit, a tracker module, an amplifying module, and a communication device in which a decrease in the efficiency of the tracker circuit and the power amplifier is reduced.

### Solution to Problem

To achieve the objective, an amplifier circuit according to an aspect of the present disclosure includes: a first power amplifier and a second power amplifier; a first tracker and a second tracker that are capable of outputting a variable power supply voltage; a first switch connected between an output port of the first tracker and an output port of the second tracker; and a second switch connected between the output port of the second tracker and the second power amplifier, and the output port of the first tracker is connected to the first power amplifier.

A tracker module according to an aspect of the present disclosure includes: a first output terminal and a second output terminal; a first tracker capable of outputting a first variable power supply voltage to the first output terminal and the second output terminal; a second tracker capable of outputting a second variable power supply voltage to the first output terminal and the second output terminal; a first switch connected between an output port of the first tracker and an output port of the second tracker; and a second switch connected between the second tracker and the second output terminal.

An amplifying module according to an aspect of the present disclosure includes: a first input terminal to which a first variable power supply voltage is applied and a second input terminal to which a second variable power supply voltage is applied; a first power amplifier and a second power amplifier; a first switch connected between the first input terminal and the second input terminal; and a second switch connected between the second power amplifier and the second input terminal, and the first power amplifier is connected to the first input terminal.

### Advantageous Effects of Disclosure

According to the present disclosure, the amplifier circuit, the tracker module, the amplifying module, and the communication device in which the efficiency decrease of the tracker circuit and the power amplifier is reduced may be provided.

### BRIEF DESCRIPTION OF DRAWINGS

FIG. 1A is a graph illustrating an example of power supply voltage changes in an average power tracking mode.

FIG. 1B is a graph illustrating an example of power supply voltage changes in an analog envelope tracking mode.

FIG. 1C is a graph illustrating an example of power supply voltage changes in a digital envelope tracking mode.

FIG. 2 is a configuration diagram of an amplifier circuit and a communication device according to an embodiment.

FIG. 3 is a configuration diagram of an amplifier circuit and a communication device according to Modification 1 of the embodiment.

FIG. 4 is a graph illustrating relationships between output current of trackers according to the embodiment and tracker efficiencies.

FIG. 5 is a configuration diagram of an amplifier circuit according to Modification 2 of the embodiment.

FIG. 6 is a configuration diagram of an amplifier circuit according to Modification 3 of the embodiment.

### DESCRIPTION OF EMBODIMENTS

Hereinafter, an embodiment of the present disclosure will be described in detail by using the drawings. The embodiment described below represents a comprehensive or specific example. Accordingly, a numerical value, a shape, a material, a component, the layout and connection form of the component, and the like that are described in the following embodiment are an example and are not intended to limit the present disclosure.

Each drawing is a schematic view appropriately subjected to emphasis, omission, or ratio control to describe the present disclosure, is not necessarily strictly illustrated, and has a shape, a positional relationship, and a ratio that are different from actual ones on occasions. Substantially the same components are denoted by the same reference numerals throughout the drawings and redundancy is omitted or simplified in some cases.

In the circuit configuration of the present disclosure, the term “connected” includes not only “directly connected” by using a connection terminal and/or a wiring conductor but also “electrically connected” with a different circuit element interposed between one component and the other component”. In addition, the phrase “connected between A and B” denotes that a component is connected between A and B and to both of A and B.

In the component layout of the present disclosure, the phrase “a component is disposed on the substrate” includes disposition of the component on the main surface of the substrate and disposition of the component in the substrate. The phrase “a component is disposed on the main surface of a substrate” includes disposition of the component above the main surface without being in contact with the main surface (for example, the component is stacked on a different component disposed in contact with the main surface), in addition to disposition of the component in contact with the main surface of the substrate. The phrase “a component is disposed on the main surface of a substrate” may also include disposition of the component in a recessed portion formed in the main surface. The term “a component is disposed in the substrate” includes: encapsulation of the component in the module substrate; disposition of the entire component between main surfaces of the substrate but exposure of part of the component from the substrate; and disposition of only part of the component in the substrate.

Terms representing a relationship between elements such as “parallel” and “perpendicular”, a term representing the shape of an element such as “rectangular”, and a numerical value range indicate not only strict meaning but also inclusion of substantially the same range, for example, an error of approximately several percent.

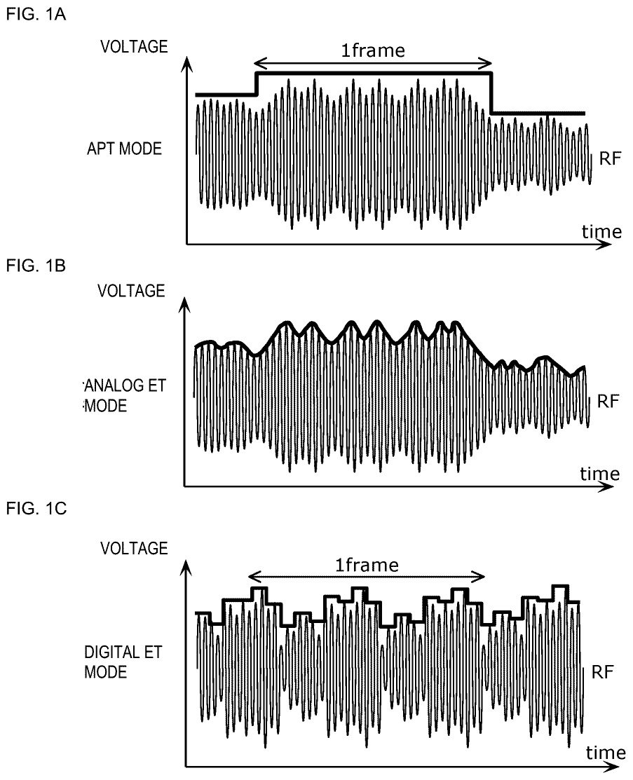

First, as technology for amplifying a radio frequency signal highly efficiently, a tracking mode in which a variable power supply voltage adjusted dynamically based on a radio frequency signal with the elapse of time is supplied to a power amplifier will be described. The tracking mode is a mode in which a power supply voltage to be supplied to an amplifier circuit is dynamically adjusted. There are some types of tracking modes, but an average power tracking (APT) mode and an envelope tracking (ET) mode (including an analog ET mode and a digital ET mode) are herein described with reference to FIGS. 1A to 1C. In each of FIGS. 1A to 1C, the horizontal axis represents time, and the vertical axis represents voltage. In addition, the thick solid line represents power supply voltage, and the thin solid line (waveform) represents modulated wave.

FIG. 1A is a graph illustrating an example of power supply voltage changes in the APT mode. In the APT mode, the level of a power supply voltage is varied to a plurality of discrete voltage levels in units of one frame. As the result, a power supply voltage signal forms a rectangular wave. In the APT mode, the voltage level of the power supply voltage is decided based on average output power. In the APT mode, the voltage level may vary in units smaller than one frame (for example, one subframe, one slot, or one symbol). APT in which the voltage level varies in units of one symbol is also called symbol power tracking (SPT) in some cases.

A frame serves as a unit of a radio frequency signal, is 10 milliseconds long, and includes 10 subframes. The subframe serves as a unit of a radio frequency signal, is one millisecond long, and includes two slots. A slot serves as a unit of a radio frequency signal, is 0.5 milliseconds long, and includes six symbols. A symbol serves as a unit of a radio frequency signal, is 71 milliseconds long, and includes a cyclic prefix (CP).

In the SPT mode, the level of the power supply voltage is modulated in units of one symbol. At this time, the voltage level is changed in the CP section. For example, the voltage level of a first symbol is changed to a higher voltage level in the CP, and the voltage level of a second symbol is changed to a lower voltage level in the CP. The voltage level of a succeeding symbol does not have to be changed. The level of the power supply voltage can be modulated based on a data signal in each symbol section.

In the present disclosure, the APT mode includes the SPT mode, and an APT module includes a module that supplies a power supply voltage to a PA module in the SPT mode.

FIG. 1B is a graph illustrating an example of power supply voltage changes in the analog ET mode. The analog ET mode is an example of an ET mode in the related art. As illustrated in FIG. 1B, in the analog ET mode, the envelope of the modulated wave is tracked by continuously varying the power supply voltage. In the analog ET mode, the power supply voltage is decided based on an envelope signal.

An envelope signal is a signal indicating the envelope of the modulated wave. The envelope value is expressed by, for example, the square root of (I2+Q2). Note that (I, Q) represents a constellation point. A constellation point is a point at which a signal modulated by the digital modulation is represented in the constellation diagram. The point (I, Q) is decided, for example, by a baseband integrated circuit (BBIC) based on sending information.

FIG. 1C is a graph illustrating an example of power supply voltage changes in the digital ET mode. As illustrated in FIG. 1C, in the digital ET mode, the envelope of the modulated wave is tracked by varying the level of the power supply voltage to a plurality of discrete voltage levels in one frame. As the result, the power supply voltage signal forms a rectangular wave. In the digital ET mode, a power supply voltage level is selected or set from among the plurality of discrete voltage levels, based on the envelope signal.

### Embodiment

### [1 Configuration of Amplifier Circuit 40 and Communication Device 5]

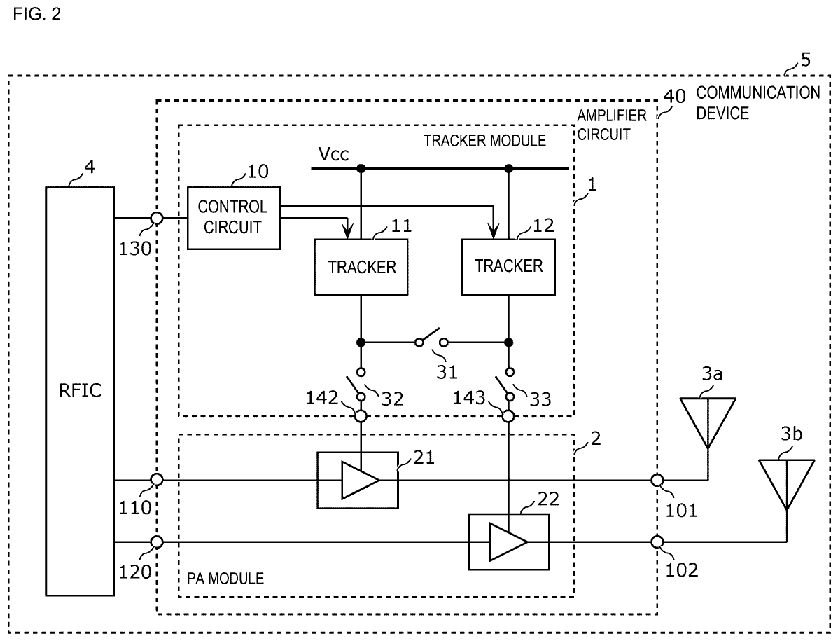

An amplifier circuit 40 and a communication device 5 according to this embodiment will be described with reference to FIG. 2.

FIG. 2 is a configuration diagram of the amplifier circuit 40 and the communication device 5 according to the embodiment. The communication device 5 according to this embodiment corresponds to a user terminal (UE: User Equipment) in a cellular network and is typically a mobile phone, a smartphone, a tablet computer, a wearable device, or the like. The communication device 5 may be an internet of things (IoT) sensor device, a medical/health care device, a vehicle, an unmanned aerial vehicle (UAV) (so-called a drone), or an automated guided vehicle (AGV).

First, the circuit configuration of the communication device 5 will be described. As illustrated in FIG. 2, the communication device 5 according to this embodiment includes the amplifier circuit 40, antennas 3a and 3b, and a radio frequency integrated circuit (RFIC) 4.

The amplifier circuit 40 includes a tracker module 1, a PA module 2, antenna connection terminals 101 and 102, signal input terminals 110 and 120, and a control signal terminal 130.

The antennas 3a and 3b are each connected to the PA module 2 included in the amplifier circuit 40 and send a radio frequency signal output from the PA module 2.

The RFIC 4 is an example of a signal processing circuit that processes a radio frequency signal. The RFIC 4 has a controller that performs control of the amplifier circuit 40. Specifically, the RFIC 4 performs the signal processing by performing upconverting or the like of a sending signal input from the BBIC (not illustrated) and outputs, to the PA module 2, a radio frequency sending signal generated by the signal processing. The RFIC 4 also outputs a digital control signal for controlling the tracker module 1 to the tracker module 1. Part or entirety of the function of the RFIC 4 as a controller may be implemented outside the RFIC 4 and may be implemented on, for example, the BBIC, the PA module 2, or the tracker module 1.

The PA module 2 is an example of an amplifying module. In response to receiving the supply of a variable power supply voltage in the APT mode, the analog ET mode, the digital ET mode, or the like from the tracker module 1, the PA module 2 amplifies a radio frequency signal input from the RFIC 4 and outputs the amplified radio frequency signal to the antennas 3a and 3b. The PA module 2 includes power amplifiers 21 and 22.

The power amplifier 21 is an example of a first power amplifier and is connected to the tracker module 1, the signal input terminal 110, and the antenna connection terminal 101. Specifically, the power supply terminal of the power amplifier 21 is connected to an output terminal 142 of the tracker module 1, the radio frequency signal input port of the power amplifier 21 is connected to the RFIC 4 with the signal input terminal 110 interposed therebetween, and the radio frequency signal output port of the power amplifier 21 is connected to the antenna 3a with the antenna connection terminal 101 interposed therebetween. The power amplifier 21 is capable of amplifying, for example, a radio frequency signal in Band A (a first band).

The power amplifier 22 is an example of a second power amplifier and is connected to the tracker module 1, the signal input terminal 120, and the antenna connection terminal 102. Specifically, the power supply terminal of the power amplifier 22 is connected to an output terminal 143 of the tracker module 1, the radio frequency signal input port of the power amplifier 22 is connected to the RFIC 4 with the signal input terminal 120 interposed therebetween, and the radio frequency signal output port of the power amplifier 22 is connected to the antenna 3b with the antenna connection terminal 102 interposed therebetween. The power amplifier 22 is capable of amplifying, for example, a radio frequency signal in Band B.

The PA module 2 may have a first filter connected between the power amplifier 21 and the antenna connection terminal 101 and a second filter connected between the power amplifier 22 and the antenna connection terminal 102. The first filter has a passband including, for example, Band A, and the second filter has a passband including, for example, Band B (a second band).

According to the configuration above of the PA module 2, the PA module 2 may amplify a radio frequency signal in at least one of Band A and Band B and output the amplified radio frequency signal to the antennas 3a and 3b.

The tracker module 1 may supply the variable power supply voltage in the APT mode, the analog ET mode, the digital ET mode, or the like to the PA module 2. The tracker module 1 includes trackers 11 and 12, switches 31, 32, and 33, a control circuit 10, and the output terminals 142 and 143.

The tracker 11 is an example of a first tracker. The tracker 11 may generate a first variable power supply voltage in response to receiving a control signal output from the control circuit 10 and apply the first variable power supply voltage to the output terminal 142 or 143. The tracker 11 is configured as, for example, a converter circuit having an inductor and a switch. The converter circuit converts a battery voltage (Vcc) into magnetic energy by using the inductor through on/off control of the switch, increases or decreases the voltage, and outputs the voltage as the first variable power supply voltage.

The tracker 12 is an example of a second tracker. The tracker 12 may generate a second variable power supply voltage in response to receiving a control signal output from the control circuit 10 and apply the first variable power supply voltage to the output terminal 142 or 143. The tracker 12 is configured as, for example, a converter circuit having an inductor and a switch. The converter circuit increases or decreases the voltage of the magnetic energy generated by using the inductor through on/off control of the switch and outputs the voltage as the second variable power supply voltage.

The switch 31 is an example of a first switch and is connected between the output port of the tracker 11 and the output port of the tracker 12. The switch 31 is composed of, for example, one single pole single throw (SPST) switch.

The switch 33 is an example of a second switch and is connected between the output port of the tracker 12 and the output terminal 143. The switch 33 is composed of, for example, one SPST switch.

The switch 32 is an example of a third switch and is connected between the output port of the tracker 11 and the output terminal 142. The switch 32 is composed of, for example, one SPST switch.

The output terminal 142 is an example of a first output terminal and is connected to the switch 32 and the power amplifier 21. The output terminal 143 is an example of a second output terminal and is connected to the switch 33 and the power amplifier 22.

The control circuit 10 is connected to the trackers 11 and 12 and the switches 31, 32, and 33 (the state of connection to the switches 31 to 33 is not illustrated). The control circuit 10 performs control of the trackers 11 and 12 and the switches 31 to 33 to output variable power supply voltages from the trackers 11 and 12, based on envelope information (an envelope signal) regarding a modulated wave input from the RFIC 4 via the control signal terminal 130 or output power information regarding the power amplifiers 21 and 22.

For example, assuming both of the variable power supply voltage of the tracker 11 and the variable power supply voltage of the tracker 12 are to be supplied to the power amplifier 21, the control circuit 10 causes the switches 31 and 32 to be in a conduction state and the switch 33 to be in a non-conduction state.

For example, assuming only the variable power supply voltage of the tracker 11 is to be supplied to the power amplifier 21, the control circuit 10 causes the switch 31 to be in the non-conduction state and the switch 32 to be in the conduction state.

For example, assuming only the variable power supply voltage of the tracker 12 is to be supplied to the power amplifier 22, the control circuit 10 causes the switch 31 to be in the non-conduction state and the switch 33 to be in the conduction state.

For example, assuming only the variable power supply voltage of the tracker 12 is to be supplied to the power amplifier 21, the control circuit 10 causes the switches 31 and 32 to be in the conduction state and the switch 33 to be in the non-conduction state.

For example, assuming only the variable power supply voltage of the tracker 11 is to be supplied to the power amplifier 22, the control circuit 10 causes the switches 31 and 33 to be in the conduction state and the switch 32 to be in the non-conduction state.

With the control circuit 10, the operations of the trackers 11 and 12 may be optimized. Specifically, the switching control of the switches 31 to 33 enables the tracker 11 to output, to the power amplifier 21 or 22, a variable power supply voltage appropriate for the output power of a corresponding one of the power amplifiers 21 and 22 and the tracker 12 to output, to the power amplifier 21 or 22, a variable power supply voltage appropriate for the output power of a corresponding one of the power amplifiers 21 and 22.

Assuming each of the power amplifiers 21 and 22 operates ordinarily in the communication device 5 according to this embodiment, the variable power supply voltage (power supply current) is supplied from the tracker 11 to the power amplifier 21, and the variable power supply voltage (power supply current) is supplied from the tracker 12 to the power amplifier 22.

However, for example, assuming an instruction to output a high Power Class high power signal is issued from a base station to the communication device 5, supplying the variable power supply voltage (power supply current) from the tracker 11 alone or the tracker 12 alone to each of the power amplifiers 21 and 22 causes a high variable power supply voltage (power supply current) and thus causes a decrease in the efficiency of the tracker 11 alone or the tracker 12 alone on occasions. The one tracker 11 or the one tracker 12 has an excessive load and thus generates heat, and thereby the efficiency of the tracker and the power amplifiers 21 and 22 is decreased on occasions.

In contrast, with the amplifier circuit 40 and the tracker module 1 according to this embodiment, any one of the power amplifiers 21 and 22 may be supplied with a variable power supply voltage in such a manner that both or one of the trackers 11 and 12 is selected by performing the switching control of the switches 31 to 33. Accordingly, a decrease in the efficiency of the trackers 11 and 12 and the power amplifiers 21 and 22 is reduced, and the efficiency increase and low power consumption in the amplifier circuit 40 are achieved.

In the amplifier circuit 40, the switch 32 does not have to be disposed, and the output port of the tracker 11 may be directly connected to the output terminal 142. In this case, the variable power supply voltages can be supplied from both of the trackers 11 and 12 to the power amplifier 21, and the variable power supply voltage can be supplied from only the tracker 12 to the power amplifier 22.

In this case, since the variable power supply voltages may be supplied from both of the trackers 11 and 12 to the power amplifier 21, the decrease in the efficiency of the trackers 11 and 12 and the power amplifier 21 is reduced, and efficiency increase and low power consumption in the amplifier circuit 40 are achieved.

The circuit configuration of the communication device 5 illustrated in FIG. 2 is an example and is not limited to this. For example, the communication device 5 does not have to include the antennas 3a and 3b.

The radio frequency signals in Band A and Band B transmitted in the PA module 2 may belong to, for example, the Low Band group (600 MHZ to 1 GHZ). The radio frequency signals in Band A and Band B transmitted in the PA module 2 may also belong to, for example, Middle/High Band (1.5 to 2.8 GHZ). The radio frequency signals in Band A and Band B transmitted in the PA module 2 may be, for example, a radio frequency signal in one of Bands n77, n78, and n79 for 5th Generation-New Radio (5G-NR).

In the amplifier circuit 40, the tracker 11 may support the analog ET mode in which the variable power supply voltage is changed to a voltage with a continuous level, based on the envelope (envelope signal) of a radio frequency input signal input to the power amplifiers 21 and 22, and the tracker 12 may support the APT mode in which the variable power supply voltage is changed to a plurality of voltages with discrete levels, based on the average output power of the radio frequency signal output from the power amplifiers 21 and 22. In this case, a first radio frequency input signal having a first channel bandwidth or a second radio frequency input signal having a second channel bandwidth wider than the first channel bandwidth is input to the power amplifier 21.

Assuming the first radio frequency input signal is to be input to the power amplifier 21, the control circuit 10 may cause the tracker 11 to supply the variable power supply voltage to the power amplifier 21. Assuming the second radio frequency input signal is to be input to the power amplifier 21, the control circuit 10 may cause the tracker 12 to supply the variable power supply voltage to the power amplifier 22.

This causes the variable power supply voltage appropriate for the channel bandwidth of the radio frequency signal to be supplied to the power amplifier 21, and thus the efficiency of the trackers 11 and 12 and the power amplifier 21 is increased.

### [2 Configuration of Amplifier Circuit 40A and Communication Device 5A According to Modification 1]

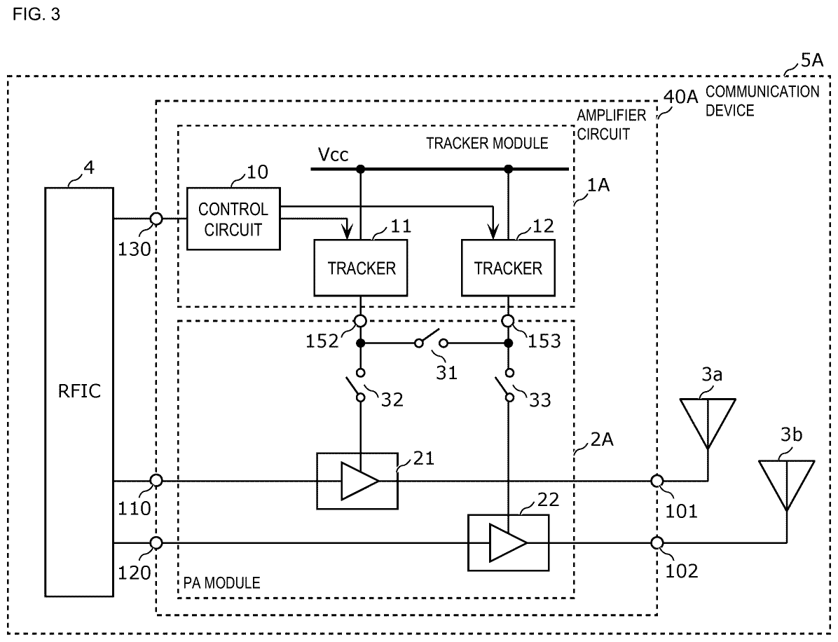

An amplifier circuit 40A and a communication device 5A according to Modification 1 will then be described with reference to FIG. 3.

FIG. 3 is a configuration diagram of the amplifier circuit 40A and the communication device 5A according to Modification 1 of the embodiment. As illustrated in the figures, the communication device 5A according to Modification 1 includes the amplifier circuit 40A, the antennas 3a and 3b, and the RFIC 4. The communication device 5A according to this modification is different from the communication device 5 according to the embodiment in the configuration of the amplifier circuit 40A.

Hereinafter, the different point in the communication device 5A according to this modification from that in the communication device 5 according to the embodiment will mainly be described.

The amplifier circuit 40A includes a tracker module 1A, a PA module 2A, the antenna connection terminals 101 and 102, the signal input terminals 110 and 120, and the control signal terminal 130.

The PA module 2A is an example of an amplifying module. In response to receiving the supply of a variable power supply voltage in the APT mode, the analog ET mode, the digital ET mode, or the like from the tracker module 1A, the PA module 2A amplifies a radio frequency signal input from the RFIC 4 and outputs the amplified radio frequency signal to the antennas 3a and 3b. The PA module 2A includes the power amplifiers 21 and 22, the switches 31, 32, and 33, and input terminals 152 and 153.

The power amplifier 21 is an example of the first power amplifier and is connected to the switch 32, the signal input terminal 110, and the antenna connection terminal 101. Specifically, the power supply terminal of the power amplifier 21 is connected to the input terminal 152 with the switch 32 interposed therebetween, the radio frequency signal input port of the power amplifier 21 is connected to the RFIC 4 with the signal input terminal 110 interposed therebetween, and the radio frequency signal output port of the power amplifier 21 is connected to the antenna 3a with the antenna connection terminal 101 interposed therebetween. The power amplifier 21 is capable of amplifying a radio frequency signal, for example, in Band A (first band).

The power amplifier 22 is an example of the second power amplifier and is connected to the switch 33, the signal input terminal 120, and the antenna connection terminal 102. Specifically, the power supply terminal of the power amplifier 22 is connected to the input terminal 153 with the switch 33 interposed therebetween, the radio frequency signal input port of the power amplifier 22 is connected to the RFIC 4 with the signal input terminal 120 interposed therebetween, and the radio frequency signal output port of the power amplifier 22 is connected to the antenna 3b with the antenna connection terminal 102 interposed therebetween. The power amplifier 22 is capable of amplifying a radio frequency signal, for example, in Band B (second band).

The switch 31 is an example of the first switch and is connected between the input terminal 152 and the input terminal 153. The switch 31 is composed of, for example, one SPST switch.

The switch 33 is an example of the second switch and is connected between the power amplifier 22 and the input terminal 153. The switch 33 is composed of, for example, one SPST switch.

The switch 32 is an example of the third switch and is connected between the power amplifier 21 and the input terminal 152. The switch 32 is composed of, for example, one SPST switch.

The input terminal 152 is an example of a first input terminal and is connected to the switch 32 and the tracker 11. A first variable power supply voltage is applied from the tracker 11 to the input terminal 152. The input terminal 153 is an example of a second input terminal and is connected to the switch 33 and the tracker 12. A second variable power supply voltage is applied from the tracker 12 to the input terminal 153.

The PA module 2A may have a first filter connected between the power amplifier 21 and the antenna connection terminal 101 and a second filter connected between the power amplifier 22 and the antenna connection terminal 102. The first filter has a passband including, for example, Band A, and the second filter has a passband including, for example, Band B (second band).

According to the configuration above of the PA module 2A, the PA module 2A may amplify a radio frequency signal in at least one of Band A and Band B and output the amplified radio frequency signal to the antennas 3a and 3b.

The tracker module 1A is capable of supplying a variable power supply voltage in the APT mode, the analog ET mode, the digital ET mode, or the like to the PA module 2A. The tracker module 1A includes the trackers 11 and 12 and the control circuit 10.

The tracker 11 is an example of the first tracker. In response to receiving a control signal output from the control circuit 10, the tracker 11 generates the first variable power supply voltage and outputs the first variable power supply voltage to the input terminal 152 of the PA module 2A.

The tracker 12 is an example of the second tracker. In response to receiving a control signal output from the control circuit 10, the tracker 12 generates the second variable power supply voltage and outputs the second variable power supply voltage to the input terminal 153 of the PA module 2A.

The control circuit 10 is connected to the trackers 11 and 12. The control circuit 10 performs control of the trackers 11 and 12 to output the variable power supply voltages from the trackers 11 and 12, based on envelope information (an envelope signal) regarding a modulated wave input from the RFIC 4 via the control signal terminal 130 or the output power information regarding the power amplifiers.

The control circuit 10 may perform control of switching between the switches 31 to 33 of the PA module 2A.

In the amplifier circuit 40A, for example, assuming both of the variable power supply voltage of the tracker 11 and the variable power supply voltage of the tracker 12 are to be supplied to the power amplifier 21, the switches 31 and 32 become in the conduction state, and the switch 33 becomes in the non-conduction state. For example, assuming only the variable power supply voltage of the tracker 11 is to be supplied to the power amplifier 21, the switch 31 becomes in the non-conduction state, and the switch 32 becomes in the conduction state. For example, assuming only the variable power supply voltage of the tracker 12 is to be supplied to the power amplifier 22, the switch 31 becomes in the non-conduction state, and the switch 33 becomes in the conduction state. For example, assuming only the variable power supply voltage of the tracker 12 is to be supplied to the power amplifier 21, the switches 31 and 32 become in the conduction state, and the switch 33 becomes in the non-conduction state. For example, assuming only the variable power supply voltage of the tracker 11 is to be supplied to the power amplifier 22, the switches 31 and 33 become in the conduction state, and the switch 32 becomes in the non-conduction state.

As described above, the operations of the trackers 11 and 12 may be optimized by performing the control of the trackers 11 and 12 and the switches 31 to 33. Specifically, the switching operations of the switches 31 to 33 enable the tracker 11 to output, to the power amplifier 21 or 22, a variable power supply voltage appropriate for the output power of a corresponding one of the power amplifiers 21 and 22 and the tracker 12 to output, to the power amplifier 21 or 22, a variable power supply voltage appropriate for the output power of a corresponding one of the power amplifiers 21 and 22.

With the amplifier circuit 40A and the PA module 2A according to this modification, any one of the power amplifiers 21 and 22 may be supplied with a variable power supply voltage in such a manner that both or one of the trackers 11 and 12 is selected by performing the switching control of the switches 31 to 33. Accordingly, the decrease in the efficiency of the trackers 11 and 12 and the power amplifiers 21 and 22 is reduced, and the efficiency increase and low power consumption in the amplifier circuit 40A are achieved.

In the amplifier circuit 40A, the switch 32 does not have to be disposed, and the power amplifier 21 may be directly connected to the input terminal 152. In this case, the variable power supply voltages can be supplied from both of the trackers 11 and 12 to the power amplifier 21, and the variable power supply voltage can be supplied from only the tracker 12 to the power amplifier 22.

In this case, since the variable power supply voltages can be supplied from both of the trackers 11 and 12 to the power amplifier 21, the decrease in the efficiency of the trackers 11 and 12 and the power amplifier 21 is reduced, and the efficiency increase and low power consumption in the amplifier circuit 40A are achieved.

The circuit configuration of the communication device 5A illustrated in FIG. 3 is an example and is not limited to this. For example, the communication device 5A does not have to include the antennas 3a and 3b.

### [3 Tracker Switching Control Based on Tracker Efficiency Characteristic]

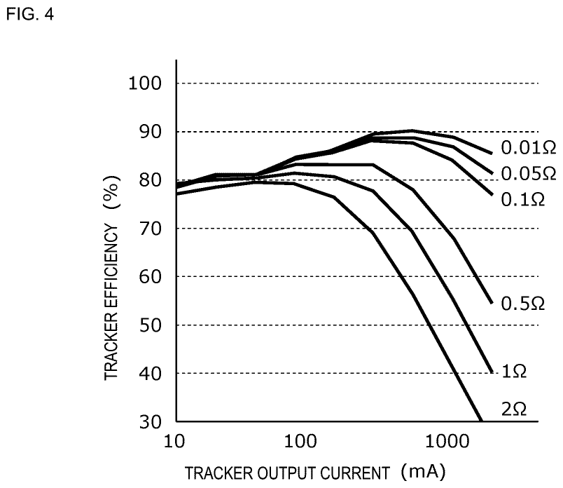

The efficiency characteristics of the trackers 11 and 12 and the switching control of the trackers 11 and 12 based on the efficiency characteristics will then be described with reference to FIG. 4.

FIG. 4 is a graph illustrating relationships between the output current of the trackers 11 and 12 according to the embodiment and tracker efficiencies. The figure illustrates an efficiency (%) (a power added efficiency) relative to output current of the tracker 11. As illustrated in the figure, the efficiency of the tracker 11 changes depending on the output current and also changes depending on a resistance (from 0.01Ω to 2Ω) serving as impedance of the power amplifier 21 considered as a load, the power amplifier 21 serving as a target for supplying the variable power supply voltage.

Assuming the power amplifier 21 is caused to perform an amplifying operation, outputting, from the tracker 11, tracker output current causing high efficiency of the tracker 11 causes the increase in the efficiency of the tracker 11 and the amplifier circuit 40. The system current of the tracker 11 required to generate tracker output current may be reduced, and thus the power consumption of the amplifier circuit 40 may be reduced.

However, the tracker output current is not decided from a high efficiency point of the tracker 11 but is decided based on an envelope signal or the output power of the power amplifier 21. Accordingly, assuming the tracker 11 is used alone, the efficiency of the tracker 11 varies.

Assuming the output current of the tracker 11 is Iₒᵤₜ, the tracker efficiency illustrated in FIG. 4 is expressed by a function f_{PAE}(Iₒᵤₜ) for the output current Iₒᵤₜ. In this case, system current I_{sys} of the tracker 11 is expressed by using Formula 1 below.

I_{sys}=Iₒᵤₜ/f_{PAE}(Iₒᵤₜ) (Formula 1)

Assuming the variable power supply voltages are to be supplied from both of the trackers 11 and 12 to the power amplifier 21, system current I_{sys1} of the tracker 11 and system current I_{sys2} of the tracker 12 are expressed by using Formula 2 below. It is assumed that the efficiency characteristic of the tracker 12 is the same as the efficiency characteristic of the tracker 11.

I_{sys1}=I_{sys2}=(Iₒᵤₜ/2)/f_{PAE}(Iₒᵤₜ/2) (Formula 2)

At this time, system current I_{sys3} serving as total current assuming the variable power supply voltages are to be supplied from both of the trackers 11 and 12 to the power amplifier 21 is expressed by using Formula 3 below.

I_{sys3}=2×(Iₒᵤₜ/2)/f_{PAE}(Iₒᵤₜ/2) (Formula 3)

On condition that Formula 4 below is satisfied, supplying the variable power supply voltages not from the tracker 11 alone but from both of the trackers 11 and 12 leads to the increase in the efficiency of the trackers assuming the power amplifier 21 is caused to operate, which is based on the viewpoint that the system current can be reduced to increase the efficiency.

I_{sys3}<I_{sys} (Formula 4)

Substituting Formula 1 and Formula 3 into Formula 4 results in Formula 5 below.

f_{PAE}(Iₒᵤₜ/2)>f_{PAE}(Iₒᵤₜ) (Formula 5)

That is, Formula 5 indicates that assuming the efficiency f_{PAE} in the tracker output current Iₒᵤₜ is lower than f_{PAE} in the tracker output current (Iₒᵤₜ/2) that is ½ of the tracker output current Iₒᵤₜ, using both of the trackers 11 and 12 rather than the tracker 11 alone leads to the increase in the tracker efficiency.

For example, it is assumed that with reference to FIG. 4, assuming the load impedance of the power amplifier 21 is 2Ω, 800 mA is required as the output current of the trackers. In this case, using the tracker 11 alone causes the tracker efficiency to be about 50% and the system current I_{sys} to be 1.6 A (=0.8 A/50%). In contrast, assuming the trackers 11 and 12 are used, 400 mA is satisfactory for the output current of each of the trackers 11 and 12. With reference to FIG. 4, the tracker efficiency is about 65% in the case of the output current of 400 mA, and the total system current I_{sys3} of the trackers 11 and 12 is 1.23 A (=2×0.4 A/65%).

That is, the tracker efficiency (50%) in the case of the output current of 800 mA is lower than the tracker efficiency (65%) in the case of the output current of 400 mA, and thus supplying the variable power supply voltages by using the two trackers 11 and 12 enables the current consumption to be reduced more.

From the viewpoint above, assuming Formula 5 above is satisfied, the control circuit 10 causes the switches 31 and 32 to be in the conduction state and the switch 33 to be in the non-conduction state. Assuming Formula 5 above is satisfied, the variable power supply voltages may thereby be supplied from both of the trackers 11 and 12 to the power amplifier 21. Accordingly, the decrease in the efficiency of the trackers 11 and 12 and the power amplifier 21 is reduced, and the efficiency increase and low power consumption in the amplifier circuit 40 are achieved.

In this embodiment, a form of switching between the two trackers 11 and 12 has been described; however, the amplifier circuit 40 according to this embodiment may have n trackers. In this case, on condition that Formula 6 below is satisfied, supplying the variable power supply voltages (tracker output current) not from the tracker 11 alone but from the n trackers leads to the increase in the efficiency of the trackers assuming the power amplifier 21 is caused to operate.

f_{PAE}(Iₒᵤₜ/n)>f_{PAE}(Iₒᵤₜ) (Formula 6)

### [4 Configuration of Amplifier Circuit 40B According to Modification 2]

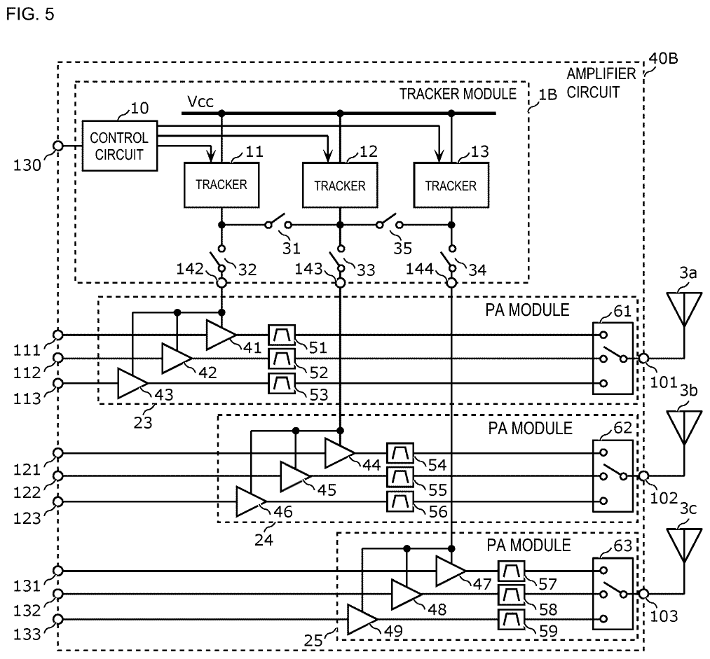

An amplifier circuit 40B according to Modification 2 will then be described with reference to FIG. 5.

FIG. 5 is a configuration diagram of the amplifier circuit 40B according to Modification 2 of the embodiment. As illustrated in the figure, the amplifier circuit 40B according to Modification 2 includes a tracker module 1B, PA modules 23, 24, and 25, the antenna connection terminals 101 and 102 and an antenna connection terminal 103, signal input terminals 111, 112, 113, 121, 122, 123, 131, 132, and 133, and the control signal terminal 130. The amplifier circuit 40B according to this modification is different from the amplifier circuit 40 according to the embodiment in the configuration of the tracker module 1B and in that the plurality of PA modules 23 to 25 are included. Hereinafter, the different points in the amplifier circuit 40B according to this modification from that in the amplifier circuit 40 according to the embodiment will mainly be described.

The antenna connection terminal 101 is connected to the PA module 23 and the antenna 3a. The antenna connection terminal 102 is connected to the PA module 24 and the antenna 3b. The antenna connection terminal 103 is connected to the PA module 25 and an antenna 3c.

In response to receiving the supply of a variable power supply voltage in the APT mode, the analog ET mode, the digital ET mode, or the like from the tracker module 1B, the PA module 23 amplifies a radio frequency signal input from the RFIC 4 and outputs the amplified radio frequency signal to the antenna 3a. The PA module 23 includes power amplifiers 41, 42, and 43, filters 51, 52, and 53, and a switch 61.

The power amplifier 41 is connected to the output terminal 142, the signal input terminal 111, and the filter 51. The power amplifier 42 is connected to the output terminal 142, the signal input terminal 112, and the filter 52. The power amplifier 43 is connected to the output terminal 142, the signal input terminal 113, and the filter 53.

The filter 51 is connected between the power amplifier 41 and the switch 61 and has a passband including Band A1. The filter 52 is connected between the power amplifier 42 and the switch 61 and has a passband including Band A2. The filter 53 is connected between the power amplifier 43 and the switch 61 and has a passband including Band A3.

The switch 61 has a common terminal and three selection terminals and performs switching between the common terminal and one of the three selection terminals. The common terminal is connected to the antenna connection terminal 101, and the three selection terminals are respectively connected to the filters 51 to 53.

The PA module 23 transmits a radio frequency signal, for example, in the Low Band group (600 MHZ to 1 GHZ).

In response to receiving the supply of a variable power supply voltage in the APT mode, the analog ET mode, the digital ET mode, or the like from the tracker module 1B, the PA module 24 amplifies a radio frequency signal input from the RFIC 4 and outputs the amplified radio frequency signal to the antenna 3b. The PA module 24 includes power amplifiers 44, 45, and 46, filters 54, 55, and 56, and a switch 62.

The power amplifier 44 is connected to the output terminal 143, the signal input terminal 121, and the filter 54. The power amplifier 45 is connected to the output terminal 143, the signal input terminal 122, and the filter 55. The power amplifier 46 is connected to the output terminal 143, the signal input terminal 123, and the filter 56.

The filter 54 is connected between the power amplifier 44 and the switch 62 and has a passband including Band B1. The filter 55 is connected between the power amplifier 45 and the switch 62 and has a passband including Band B2. The filter 56 is connected between the power amplifier 46 and the switch 62 and has a passband including Band B3.

The switch 62 has a common terminal and three selection terminals and performs switching between the common terminal and one of the three selection terminals. The common terminal is connected to the antenna connection terminal 102, and the three selection terminals are respectively connected to the filters 54 to 56.

The PA module 24 transmits a radio frequency signal, for example, in Middle/High Band (1.5 to 2.8 GHZ).

In response to receiving the supply of a variable power supply voltage in the APT mode, the analog ET mode, the digital ET mode, or the like from the tracker module 1B, the PA module 25 amplifies a radio frequency signal input from the RFIC 4 and outputs the amplified radio frequency signal to the antenna 3c. The PA module 25 includes power amplifiers 47, 48, and 49, filters 57, 58, and 59, and a switch 63.

The power amplifier 47 is connected to an output terminal 144, the signal input terminal 131, and the filter 57. The power amplifier 48 is connected to the output terminal 144, the signal input terminal 132, and the filter 58. The power amplifier 49 is connected to the output terminal 144, the signal input terminal 133, and the filter 59.

The filter 57 is connected between the power amplifier 47 and the switch 63 and has a passband including Band C1. The filter 58 is connected between the power amplifier 48 and the switch 63 and has a passband including Band C2. The filter 59 is connected between the power amplifier 49 and the switch 63 and has a passband including Band C3.

The switch 63 has a common terminal and three selection terminals and performs switching between the common terminal and one of the three selection terminals. The common terminal is connected to the antenna connection terminal 103, and the three selection terminals are respectively connected to the filters 57 to 59.

The PA module 25 transmits a radio frequency signal, for example, in at least one of Bands n77, n78, and n79 for 5G-NR.

According to the configuration above of the PA modules 23 to 25, at least two of the radio frequency signal transmitted through the PA module 23, the radio frequency signal transmitted through the PA module 24, and the radio frequency signal transmitted through the PA module 25 may be sent simultaneously.

The tracker module 1B is capable of supplying a variable power supply voltage in the APT mode, the analog ET mode, the digital ET mode, or the like to the PA modules 23, 24, and 25. The tracker module 1B includes the trackers 11 and 12 and a tracker 13, the switches 31, 32, and 33 and switches 34 and 35, the control circuit 10, and the output terminals 142, 143, and 144.

The tracker 11 is an example of the first tracker. In response to receiving a control signal output from the control circuit 10, the tracker 11 generates a first variable power supply voltage and applies the first variable power supply voltage to the output terminal 142, 143, or 144.

The tracker 12 is an example of the second tracker. In response to receiving a control signal output from the control circuit 10, the tracker 12 generates a second variable power supply voltage and applies the second variable power supply voltage to the output terminal 142, 143, or 144.

In response to receiving a control signal output from the control circuit 10, the tracker 13 generates a third variable power supply voltage and applies the third variable power supply voltage to the output terminal 142, 143, or 144.

The switch 31 is an example of the first switch and is connected between the output port of the tracker 11 and the output port of the tracker 12. The switch 33 is an example of the second switch and is connected between the output port of the tracker 12 and the output terminal 143. The switch 32 is an example of the third switch and is connected between the output port of the tracker 11 and the output terminal 142. The switch 35 is connected between the output port of the tracker 12 and the output port of the tracker 13. The switch 34 is connected between the output port of the tracker 13 and the output terminal 144.

The output terminal 142 is an example of the first output terminal and is connected to the switch 32 and the power amplifiers 41 to 43. The output terminal 143 is an example of the second output terminal and is connected to the switch 33 and the power amplifiers 44 to 46. The output terminal 144 is connected to the switch 34 and the power amplifiers 47 to 49.

The control circuit 10 is connected to the trackers 11 to 13 and the switches 31 to 35 (the state of connection to the switches 31 to 35 is not illustrated). The control circuit 10 performs control of the trackers 11 to 13 and the switches 31 to 35 to output variable power supply voltages from the trackers 11 to 13, based on envelope information (an envelope signal) regarding a modulated wave input from the RFIC 4 via the control signal terminal 130 or the output power information regarding the power amplifiers.

With the control circuit 10, the operations of the trackers 11 to 13 may be optimized. Specifically, the switching control of the switches 31 to 35 enables the trackers 11 to 13 to output, to the power amplifiers 41 to 49, variable power supply voltages appropriate for the output power of the respective power amplifiers 41 to 49.

With the amplifier circuit 40B according to this modification, any one of the power amplifiers 41 to 49 may be supplied with a variable power supply voltage in such a manner that at least one of the trackers 11 to 13 is selected by performing the switching control of the switches 31 to 35. Accordingly, the decrease in the efficiency of the trackers 11 to 13 and the power amplifiers 41 to 49 is reduced, and the efficiency increase and low power consumption in the amplifier circuit 40B are achieved.

In the amplifier circuit 40B, the number of trackers may be greater than or equal to 4. It suffices that the number of PA modules may be greater than or equal to 1. Any one of the switches 32, 33, and 34 does not have to be provided.

The power amplifiers 41 to 43 of the PA module 23 are all connected to the output terminal 142 but may be connected to a different output terminal. That is, the power amplifiers included in the same PA module may be connected to respective different output terminals. The power amplifiers included in the different PA modules may be connected to the same output terminal.

The PA modules 23 to 25 do not have to be connected to a corresponding different one of the antennas 3a to 3c and may also be connected to the same antenna.

The amplifier circuit 40B according to this modification may be mounted on a mother board together with the antennas 3a to 3c and the RFIC 4. In this case, the tracker module 1B is mounted on a first module laminate, the PA module 23 is mounted on a second module laminate, the PA module 24 is mounted on a third module laminate, and the PA module 25 is mounted on a fourth module laminate. The first module laminate, the second module laminate, the third module laminate, and the fourth module laminate are disposed on the mother board.

Alternatively, the tracker module 1B may be included in a first semiconductor IC, the PA module 23 may be included in a second semiconductor IC, the PA module 24 may be included in a third semiconductor IC, the PA module 25 may be included in a fourth semiconductor IC, the first semiconductor IC, the second semiconductor IC, the third semiconductor IC, and the fourth semiconductor IC may be disposed on the mother board.

The switches 31 to 35 may also be included in a switch IC different from the first semiconductor IC.

The first to fourth semiconductor ICs and the switch IC may be formed by using, for example, a complementary metal oxide semiconductor (CMOS) and specifically, may be manufactured in a silicon on insulator (SOI) process.

### [5 Configuration of Amplifier Circuit 40C According to Modification 3]

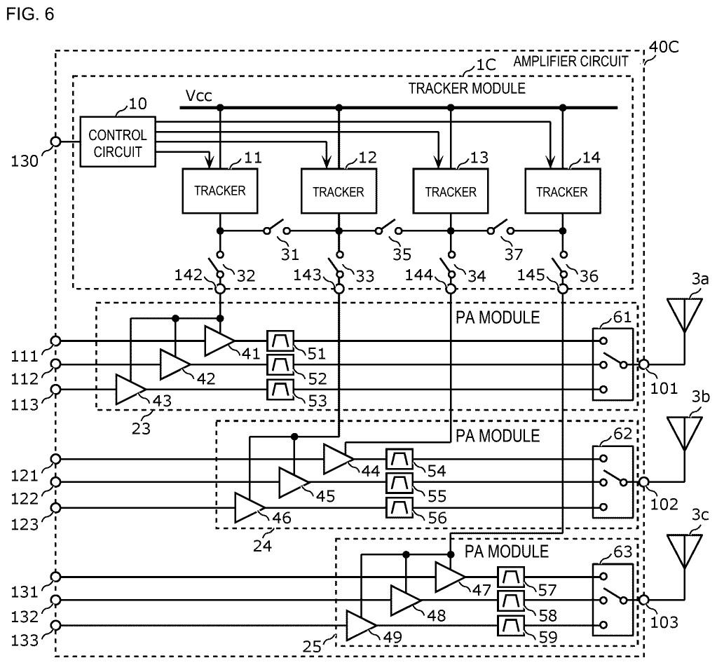

An amplifier circuit 40C according to Modification 3 will then be described with reference to FIG. 6.

FIG. 6 is a configuration diagram of the amplifier circuit 40C according to Modification 3 of the embodiment. As illustrated in the figure, the amplifier circuit 40C according to Modification 3 includes a tracker module 1C, the PA modules 23, 24, and 25, the antenna connection terminals 101 and 102 and an antenna connection terminal 103, the signal input terminals 111, 112, 113, 121, 122, 123, 131, 132, and 133, and the control signal terminal 130. The amplifier circuit 40C according to this modification is different from the amplifier circuit 40B according to Modification 2 in the configurations of the tracker module 1C and the PA module 24. Hereinafter, the description of the same configuration of the amplifier circuit 40C according to this modification as that of the amplifier circuit 40B according to Modification 2 is omitted, and the different configurations thereof are mainly described.

In response to receiving the supply of a variable power supply voltage in the APT mode, the analog ET mode, the digital ET mode, or the like from the tracker module 1C, the PA module 23 amplifies a radio frequency signal input from the RFIC 4 and outputs the amplified radio frequency signal to the antenna 3a. The PA module 23 includes the power amplifiers 41, 42, and 43, the filters 51, 52, and 53, and the switch 61.

The power amplifier 41 is connected to the output terminal 142, the signal input terminal 111, and the filter 51. The power amplifier 42 is connected to the output terminal 142, the signal input terminal 112, and the filter 52. The power amplifier 43 is connected to the output terminal 142, the signal input terminal 113, and the filter 53.

In response to receiving the supply of a variable power supply voltage in the APT mode, the analog ET mode, the digital ET mode, or the like from the tracker module 1C, the PA module 24 amplifies a radio frequency signal input from the RFIC 4 and outputs the amplified radio frequency signal to the antenna 3b. The PA module 24 includes the power amplifiers 44, 45, and 46, the filters 54, 55, and 56, and the switch 62.

The power amplifier 44 is an example of the second power amplifier and is connected to the output terminal 144, the signal input terminal 121, and the filter 54. The power amplifier 45 is an example of the first power amplifier and is connected to the output terminal 143, the signal input terminal 122, and the filter 55. The power amplifier 46 is an example of a third power amplifier and is connected to the output terminal 143, the signal input terminal 123, and the filter 56.

In response to receiving the supply of a variable power supply voltage in the APT mode, the analog ET mode, the digital ET mode, or the like from the tracker module 1C, the PA module 25 amplifies a radio frequency signal input from the RFIC 4 and outputs the amplified radio frequency signal to the antenna 3c. The PA module 25 includes the power amplifiers 47, 48, and 49, the filters 57, 58, and 59, and the switch 63.

The power amplifier 47 is connected to an output terminal 145, the signal input terminal 131, and the filter 57. The power amplifier 48 is connected to the output terminal 145, the signal input terminal 132, and the filter 58. The power amplifier 49 is connected to the output terminal 145, the signal input terminal 133, and the filter 59.

According to the configuration above of the PA modules 23 to 25, at least two of the radio frequency signal transmitted through the PA module 23, the radio frequency signal transmitted through the PA module 24, and the radio frequency signal transmitted through the PA module 25 may be sent simultaneously.

The tracker module 1C is capable of supplying a variable power supply voltage in the APT mode, the analog ET mode, the digital ET mode, or the like to the PA modules 23, 24, and 25. The tracker module 1C includes the trackers 11, 12, and 13 and a tracker 14, the switches 31, 32, 33, 34, and 35 and switches 36 and 37, the control circuit 10, and the output terminals 142, 143, 144, and 145.

In response to receiving a control signal output from the control circuit 10, the tracker 11 generates a variable power supply voltage and outputs the variable power supply voltage to the output terminal 142, 143, 144, or 145.

The tracker 12 is an example of the first tracker. In response to receiving a control signal output from the control circuit 10, the tracker 12 generates a variable power supply voltage and outputs the variable power supply voltage to the output terminal 142, 143, 144, or 145.

The tracker 13 is an example of the second tracker. In response to receiving a control signal output from the control circuit 10, the tracker 13 generates a variable power supply voltage and outputs the variable power supply voltage to the output terminal 142, 143, 144, or 145.

In response to receiving a control signal output from the control circuit 10, the tracker 14 generates a variable power supply voltage and outputs the variable power supply voltage to the output terminal 142, 143, 144, or 145.

The switch 31 is connected between the output port of the tracker 11 and the output port of the tracker 12. The switch 35 is an example of the first switch and is connected between the output port of the tracker 12 and the output port of the tracker 13. The switch 37 is connected between the output port of the tracker 13 and the output port of the tracker 14. The switch 32 is connected between the output port of the tracker 11 and the output terminal 142. The switch 33 is an example of the third switch and is connected between the output port of the tracker 12 and the output terminal 143. The switch 34 is an example of the second switch and is connected between the output port of the tracker 13 and the output terminal 144. The switch 36 is connected between the output port of the tracker 14 and the output terminal 145.

The output terminal 142 is connected to the switch 32 and the power amplifiers 41 to 43. The output terminal 143 is an example of the first output terminal and is connected to the switch 33 and the power amplifiers 45 and 46. The output terminal 144 is an example of the second output terminal and is connected to the switch 34 and the power amplifier 44. The output terminal 145 is connected to the switch 36 and the power amplifiers 47 to 49.

The control circuit 10 is connected to the trackers 11 to 14 and the switches 31 to 37 (the connection state is not illustrated). The control circuit 10 performs control of the trackers 11 to 14 and the switches 31 to 37 to output variable power supply voltages from the trackers 11 to 14, based on envelope information (an envelope signal) regarding a modulated wave input from the RFIC 4 via the control signal terminal 130, the output power information regarding the power amplifiers, or the like.

With the control circuit 10, the operations of the trackers 11 to 14 may be optimized. Specifically, the switching control of the switches 31 to 37 enables the trackers 11 to 14 to output, to the power amplifiers 41 to 49, variable power supply voltages appropriate for the output power of the respective power amplifiers 41 to 49.

With the amplifier circuit 40C according to this modification, any one of the power amplifiers 41 to 49 may be supplied with a variable power supply voltage in such a manner that at least one of the trackers 11 to 14 is selected by performing the switching control of the switches 31 to 37. Accordingly, the decrease in the efficiency of the trackers 11 to 14 and the power amplifiers 41 to 49 is reduced, and the efficiency increase and low power consumption in the amplifier circuit 40C are achieved.

In the amplifier circuit 40C, it suffices that the number of trackers is greater than or equal to 2. It suffices that the number of PA modules is greater than or equal to 1. Any one of the switches 32, 33, 34, and 36 does not have to be provided.

The power amplifiers 41 to 43 of the PA module 23 are all connected to the output terminal 142 but may be connected to a different output terminal. The power amplifiers 47 to 49 of the PA module 25 are all connected to the output terminal 145 but may be connected to a different output terminal. That is, the power amplifiers included in the same PA module may be connected to respective different output terminals. The power amplifiers included in the different PA modules may be connected to the same output terminal.

The PA modules 23 to 25 do not have to be connected to a corresponding different one of the antennas 3a to 3c and may be connected to the same antenna.

### 6 Advantageous Effects and the Like

As described above, the amplifier circuit 40 according to this embodiment includes the power amplifiers 21 and 22, the trackers 11 and 12 capable of outputting the variable power supply voltage, the switch 31 connected between the output port of the tracker 11 and the output port of the tracker 12, the switch 33 connected between the output port of the tracker 12 and the power amplifier 22, and the output port of the tracker 11 is connected to the power amplifier 21.

Assuming each of the power amplifiers 21 and 22 operates ordinarily, a variable power supply voltage (power supply current) is supplied from the tracker 11 to the power amplifier 21, and a variable power supply voltage (power supply current) is supplied from the tracker 12 to the power amplifier 22. However, for example, assuming an instruction to output a high Power Class high power signal is issued, supplying the variable power supply voltage (power supply current) from the tracker 11 alone to the power amplifier 21 causes a high variable power supply voltage (power supply current) and thus causes a decrease in the efficiency of the tracker 11. In addition, the tracker 11 has an excessive load and thus generates heat, and thereby the efficiency of the tracker 11 and the power amplifier 21 is decreased on occasions.

In contrast, the amplifier circuit 40 enables the variable power supply voltage to be supplied to the power amplifier 21 in such a manner that both or one of the trackers 11 and 12 is selected by performing the switching control of the switches 31 and 33. Accordingly, the decrease in the efficiency of the tracker 11 and the power amplifier 21 is reduced, and the efficiency increase and low power consumption in the amplifier circuit 40 are achieved.

In addition, for example, the amplifier circuit 40 may further include the switch 32 connected between the output port of the tracker 11 and the power amplifier 21.

Any one of the power amplifiers 21 and 22 may thereby be supplied with a variable power supply voltage in such a manner that both or one of the trackers 11 and 12 is selected by performing the switching control of the switches 31 to 33. Accordingly, the decrease in the efficiency of the trackers 11 and 12 and the power amplifiers 21 and 22 is reduced, and the efficiency increase and low power consumption in the amplifier circuit 40 are achieved.

For example, in the amplifier circuit 40, the tracker 11 may be capable of outputting, to the power amplifier 21, an envelope signal or a variable power supply voltage appropriate for the average output power of the power amplifier 21, and the tracker 12 may be capable of outputting, to the power amplifier 22, a variable power supply voltage appropriate for an envelope signal or the average output power of the power amplifier 22.

The efficiency of the power amplifiers 21 and 22 may thereby be increased.

For example, the amplifier circuit 40 may further include the control circuit 10 connected to the trackers 11 and 12 and the switches 31 and 33.

Accordingly, the operations of the trackers 11 and 12 may be optimized by controlling the trackers 11 and 12 and the switches 31 and 33, and thus the efficiency of the trackers 11 and 12 may be increased.

For example, in the amplifier circuit 40, assuming the variable power supply voltage of the tracker 11 and the variable power supply voltage of the tracker 12 is to be supplied to the power amplifier 21, the control circuit 10 may cause the switch 31 to be in the conduction state and the switch 33 to be in the non-conduction state. Assuming only the variable power supply voltage of the tracker 11 is to be supplied to the power amplifier 21, the control circuit 10 may cause the switch 31 to be in the non-conduction state. Assuming only the variable power supply voltage of the tracker 12 is to be supplied to the power amplifier 22, the control circuit 10 may cause the switch 31 to be in the non-conduction state and the switch 33 to be in the conduction state.

Any one of the power amplifiers 21 and 22 may thereby be supplied with a variable power supply voltage in such a manner that both or one of the trackers 11 and 12 to be selected by performing the switching control of the switches 31 and 33 causes. Accordingly, the decrease in the efficiency of the trackers 11 and 12 and the power amplifiers 21 and 22 is reduced, and the efficiency increase and low power consumption in the amplifier circuit 40 are achieved.

For example, in the amplifier circuit 40, the output current of the tracker 11 is Iₒᵤₜ, and the efficiency of the tracker 11 that is expressed as the function of the output current Iₒᵤₜ is f_{PAE}(Iₒᵤₜ). Assuming f_{PAE}(Iₒᵤₜ/2)>f_{PAE}(Iₒᵤₜ) is satisfied, the control circuit 10 may cause the switch 31 to be in the conduction state and the switch 33 to be in the non-conduction state.

Assuming the formula is satisfied, the variable power supply voltages may thereby be supplied from both of the trackers 11 and 12 to the power amplifier 21. Accordingly, the decrease in the efficiency of the trackers 11 and 12 and the power amplifier 21 is reduced, and the efficiency increase and low power consumption in the amplifier circuit 40 are achieved.

For example, the amplifier circuit 40 may further include the first filter connected to the output port of the power amplifier 21 and having the passband including Band A and the second filter that is connected to the output port of the power amplifier 22 and that has the passband including Band B different from Band A.

Accordingly, the power amplifiers 21 and 22 are not amplifiers in cascading connection that are disposed at a stage and a subsequent stage and amplify radio frequency signals in different bands.

For example, in the amplifier circuit 40C according to Modification 3, the power amplifier 45 is connected to one end of the switch 33, the power amplifier 44 is connected to one end of the switch 34, and the power amplifier 46 is connected to one end of the switch 33.

Like the power amplifier 45, a variable power supply voltages may be supplied from both of the trackers 12 and 13 the power amplifier 46.

For example, in the amplifier circuit 40, the tracker 11 may support the analog ET mode in which a variable power supply voltage is changed into a voltage with a continuous level, based on the envelope of the radio frequency input signal input to the power amplifiers 21 and 22, the tracker 12 may support the APT mode in which a variable power supply voltage is changed to a plurality of voltages with discrete levels, based on the average output power of the radio frequency signal output from the power amplifiers 21 and 22, the first radio frequency input signal having the first channel bandwidth and the second radio frequency input signal having the second channel bandwidth wider than the first channel bandwidth may be input to the power amplifier 21, and the control circuit 10 may cause the tracker 11 to supply the variable power supply voltage to the power amplifier 21 assuming the first radio frequency input signal is to be input to the power amplifier 21 and may cause the tracker 12 to supply the variable power supply voltage to the power amplifier 21 assuming the second radio frequency input signal is to be input to the power amplifier 21.

This causes the variable power supply voltage to be supplied to the power amplifier 21 appropriately for the channel bandwidth of the radio frequency signal, and thus the efficiency of the trackers 11 and 12 and the power amplifier 21 is increased.

The tracker module 1 according to this embodiment includes the output terminals 142 and 143, the tracker 11 capable of outputting the first variable power supply voltage to the output terminals 142 and 143, the tracker 12 capable of outputting the second variable power supply voltage to the output terminals 142 and 143, the switch 31 connected between the output port of the tracker 11 and the output port of the tracker 12, and the switch 33 connected between the tracker 12 and the output terminal 143.

This enables the power amplifier 21 connected to the output terminal 142 to be supplied with a variable power supply voltage in such a manner that both or one of the trackers 11 and 12 is selected by performing the switching control of the switches 31 and 33. Accordingly, the decrease in the efficiency of the tracker 11 is reduced, and the efficiency increase and low power consumption in the amplifier circuit 40 are achieved.

For example, the tracker module 1 may further include the switch 32 connected between the tracker 11 and the output terminal 142.

This enables each power amplifier 21 or 22 connected to a corresponding one of the output terminals 142 and 143 to be supplied with a variable power supply voltage in such a manner that both or one of the trackers 11 and 12 is selected by performing the switching control of the switches 31 to 33. Accordingly, the decrease in the efficiency of the trackers 11 and 12 is reduced, and the efficiency increase and low power consumption in the amplifier circuit 40 are achieved.

For example, the tracker module 1 may further include the control circuit 10 connected to the trackers 11 and 12 and the switches 31 and 33.

Accordingly, the operations of the trackers 11 and 12 may be optimized by controlling the trackers 11 and 12 and the switches 31 and 33, and thus the efficiency of the trackers 11 and 12 may be increased.

For example, in the tracker module 1, assuming the first variable power supply voltage and the second variable power supply voltage is to be applied to the output terminal 142, the control circuit 10 may cause the switch 31 to be in the conduction state and the switch 33 to be in the non-conduction state. Assuming only the first variable power supply voltage is to be supplied to the output terminal 142, the control circuit 10 may cause the switch 31 to be in the non-conduction state. Assuming only the second variable power supply voltage is to be supplied to the output terminal 143, the control circuit 10 may cause the switch 31 to be in the non-conduction state and the switch 33 to be in the conduction state.

This enables the output terminal 142 to apply a variable power supply voltage in such a manner that both or one of the trackers 11 and 12 is selected by performing the switching control of the switches 31 and 33. Accordingly, the decrease in the efficiency of the trackers 11 and 12 is reduced.

The PA module 2A according to Modification 1 includes the input terminal 152 to which the first variable power supply voltage is applied and the input terminal 153 to which the second variable power supply voltage is applied, the power amplifiers 21 and 22, the switch 31 connected between the input terminal 152 and the input terminal 153, and the switch 33 connected between the power amplifier 22 and the input terminal 153, and the power amplifier 21 is connected to the input terminal 152.

The variable power supply voltages may thereby be supplied from both of the trackers 11 and 12 to the power amplifier 21. Accordingly, the decrease in the efficiency of the trackers 11 and 12 and the power amplifier 21 is reduced, and the efficiency increase and low power consumption in the amplifier circuit 40A are achieved.

The PA module 2A according to Modification 1 may further include the switch 32 connected between the power amplifier 21 and the input terminal 152.

This enables the power amplifier 21 to be supplied with power supply voltages from both of the trackers 11 and 12 and also the power amplifier 22 to be supplied with power supply voltages from both of the trackers 11 and 12 and thus the efficiency increase and low power consumption in the amplifier circuit 40A to be achieved.

The PA module 2A according to Modification 1 may further include the first filter connected to the output port of the power amplifier 21 and having the passband including Band A and the second filter that is connected to the output port of the power amplifier 22 and that has the passband including Band B different from Band A.

Accordingly, the power amplifiers 21 and 22 are not amplifiers in cascading connection that are disposed at a stage and a subsequent stage and amplify radio frequency signals in different bands.

In the PA module 2A according to Modification 1, the power amplifier 21 may be connected to one end of the switch 32, the power amplifier 22 may be connected to one end of the switch 33, and the PA module 2A may further include the third power amplifier connected to one end of the switch 32.

This enables the third power amplifier to be supplied with variable power supply voltages from both of the trackers 11 and 12, like the power amplifier 21.

The communication device 5 according to this embodiment includes the RFIC 4 that processes the radio frequency signal, the tracker module 1 connected to the RFIC 4, and the PA module 2 including the power amplifiers 21 and 22 that receives the variable power supply voltage from the tracker module 1.

The communication device 5 may thereby achieve the advantageous effects of the tracker module 1.

The communication device 5A according to this embodiment also includes the RFIC 4 that processes the radio frequency signal, the PA module 2A that transmits a radio frequency signal between the RFIC 4 and each of the antennas 3a and 3b, and the tracker module 1A including the trackers 11 and 12 that is connected to the RFIC 4 and that supplies the variable power supply voltage to the PA module 2A.

The communication device 5A may thereby achieve the effects of the PA module 2A.

### Other Embodiments

The amplifier circuit, the tracker module, the amplifying module, and the communication device according to the present disclosure have heretofore been described based on the embodiment and the modifications; however, the amplifier circuit, the tracker module, the amplifying module, and the communication device according to the present disclosure are not limited to those in the embodiment and the modifications above. Another embodiment implemented by combining any components in the above-described embodiment and modifications, a modification obtained by applying, to any of the embodiment and the modifications conceived of those skilled in the art without departing from the spirit of the present disclosure, and various types of equipment having any of the amplifier circuit, the tracker module, the amplifying module, and the communication device that are built therein are also included in the present disclosure.

For example, in the circuit configuration of the amplifier circuit, the tracker module, the amplifying module, and the communication device according to the embodiment and the modifications above, another circuit element, another wiring line, or the like may be inserted into a path connecting a circuit element and a signal path that are disclosed in the drawings.

The features of the amplifier circuit, the tracker module, the amplifying module, and the communication device described based on the embodiment are described below.

<1>

An amplifier circuit includes:
a first power amplifier and a second power amplifier;
a first tracker and a second tracker that are capable of outputting a variable power supply voltage;
a first switch connected between an output port of the first tracker and an output port of the second tracker; and
a second switch connected between the output port of the second tracker and the second power amplifier, and
the output port of the first tracker is connected to the first power amplifier.
   <2>

The amplifier circuit according to <1> further includes:
a third switch connected between the output port of the first tracker and the first power amplifier.
   <3>

In the amplifier circuit according to <1> or <2>,
the first tracker is capable of outputting, to the first power amplifier, an envelope signal or a variable power supply voltage appropriate for average output power of the first power amplifier, and
the second tracker is capable of outputting, to the second power amplifier, an envelope signal or a variable power supply voltage appropriate for average output power of the second power amplifier.
   <4>

The amplifier circuit according to any one of <1> to <3> further includes:
a control circuit connected to the first tracker, the second tracker, the first switch, and the second switch.
   <5>>

In the amplifier circuit according to <4>,
the control circuit
causes the first switch to be in a conduction state and the second switch to be in a non-conduction state assuming the variable power supply voltage of the first tracker and the variable power supply voltage of the second tracker are to be supplied to the first power amplifier,
causes the first switch to be in the non-conduction state assuming only the variable power supply voltage of the first tracker is to be supplied to the first power amplifier, and
causes the first switch to be in the non-conduction state and the second switch to be in the conduction state assuming only the variable power supply voltage of the second tracker is to be supplied to the second power amplifier.
   <6>

In the amplifier circuit according to <4> or <5>,
in a case where output current of the first tracker is Iₒᵤₜ and efficiency of the first tracker expressed as a function of the output current Iₒᵤₜ is f_{PAE}(Iₒᵤₜ),
the control circuit
causes the first switch to be in the conduction state and the second switch to be in the non-conduction state
assuming f_{PAE}(Iₒᵤₜ/2)>f_{PAE}(Iₒᵤₜ) is satisfied.
   <7>

The amplifier circuit according to any one of <1> to <6> further includes:
a first filter that is connected to an output port of the first power amplifier and that has a passband including a first band; and
a second filter that is connected to an output port of the second power amplifier and that has a passband including a second band different from the first band.
   <8>

In the amplifier circuit according to <2>,
the first power amplifier is connected to an end of the third switch,
the amplifier circuit further including a third power amplifier connected to the end.
   <9>

In the amplifier circuit according to <4> or <5>,
the first tracker supports an analog envelope tracking mode in which the variable power supply voltage is changed to a voltage with a continuous level, based on an envelope of a radio frequency input signal input to the first power amplifier and the second power amplifier,
the second tracker supports an average power tracking mode in which the variable power supply voltage is changed to a plurality of voltages with discrete levels, based on average output power of radio frequency signals output from the first power amplifier and the second power amplifier,
a first radio frequency input signal having a first channel bandwidth and a second radio frequency input signal having a second channel bandwidth wider than the first channel bandwidth are input to the first power amplifier, and
the control circuit
causes the first tracker to supply the variable power supply voltage to the first power amplifier assuming the first radio frequency input signal is to be input to the first power amplifier, and
causes the second tracker to supply the variable power supply voltage to the first power amplifier assuming the second radio frequency input signal is to be input to the first power amplifier.
   <10>

A tracker module includes:
a first output terminal and a second output terminal;
a first tracker capable of outputting a first variable power supply voltage to the first output terminal and the second output terminal;
a second tracker capable of outputting a second variable power supply voltage to the first output terminal and the second output terminal;
a first switch connected between an output port of the first tracker and an output port of the second tracker; and
a second switch connected between the second tracker and the second output terminal.
   <11>

The tracker module according to <10> further includes:
a third switch connected between the first tracker and the first output terminal.
   <12>

The tracker module according to <10> or <11> further includes:
a control circuit connected to the first tracker, the second tracker, the first switch, and the second switch.
   <13>

In the tracker module according to <12>, the control circuit
causes the first switch to be in a conduction state and the second switch to be in a non-conduction state assuming the first variable power supply voltage and the second variable power supply voltage are to be applied to the first output terminal,
causes the first switch to be in the non-conduction state assuming only the first variable power supply voltage is to be supplied to the first output terminal, and
causes the first switch to be in the non-conduction state and the second switch to be in the conduction state assuming only the second variable power supply voltage is to be supplied to the second output terminal.
   <14>

An amplifying module includes:
a first input terminal to which a first variable power supply voltage is applied and a second input terminal to which a second variable power supply voltage is applied;
a first power amplifier and a second power amplifier;
a first switch connected between the first input terminal and the second input terminal; and
a second switch connected between the second power amplifier and the second input terminal, and
the first power amplifier is connected to the first input terminal.
   <15>

The amplifying module according to <14> further includes:
a third switch connected between the first power amplifier and the first input terminal.
   <16>

The amplifying module according to <14> or <15> further includes:
a first filter that is connected to an output port of the first power amplifier and that has a passband including a first band; and
a second filter that is connected to an output port of the second power amplifier and that has a passband including a second band different from the first band.
   <17>

In the amplifying module according to <15>,
the first power amplifier is connected to an end of the third switch,
the amplifying module further including a third power amplifier connected to the end.
   <18>

A communication device includes:
a signal processing circuit that processes a radio frequency signal;
the tracker module according to any one of <10> to <12> that is connected to the signal processing circuit; and
an amplifying module including a power amplifier that receives a variable power supply voltage from the tracker module.
   <19>

A communication device includes:
a signal processing circuit that processes a radio frequency signal;

the amplifying module according to any one of <14> to <17> that transmits the radio frequency signal between the signal processing circuit and an antenna; and
a tracker module including a tracker that is connected to the signal processing circuit and that supplies the variable power supply voltage to the amplifying module.

### INDUSTRIAL APPLICABILITY

The present disclosure is widely usable, as a power supply circuit disposed in a front end unit supporting a multiband or a communication device, for communication equipment such as a mobile phone.

### REFERENCE SIGNS LIST

1, 1A, 1B, 1C tracker module
2, 2A, 23, 24, 25 PA module
3a, 3b, 3c antenna
4 RFIC
5, 5A communication device
10 control circuit
11, 12, 13, 14 tracker
21, 22, 41, 42, 43, 44, 45, 46, 47, 48, 49 power amplifier
31, 32, 33, 34, 35, 36, 37, 61, 62, 63 switch
40, 40A, 40B, 40C amplifier circuit
51, 52, 53, 54, 55, 56, 57, 58, 59 filter
101, 102, 103 antenna connection terminal
110, 111, 112, 113, 120, 121, 122, 123, 131, 132, 133 signal input terminal
130 control signal terminal
142, 143, 144, 145 output terminal
152, 153 input terminal

1. An amplifier circuit comprising:
a first power amplifier and a second power amplifier;
a first tracker and a second tracker that are capable of outputting a variable power supply voltage;
a first switch connected between an output port of the first tracker and an output port of the second tracker; and
a second switch connected between the output port of the second tracker and the second power amplifier,
wherein the output port of the first tracker is connected to the first power amplifier.

2. The amplifier circuit according to claim 1, further comprising:
a third switch connected between the output port of the first tracker and the first power amplifier.

3. The amplifier circuit according to claim 2,
wherein the first tracker is capable of outputting, to the first power amplifier, an envelope signal or a variable power supply voltage appropriate for average output power of the first power amplifier, and
wherein the second tracker is capable of outputting, to the second power amplifier, an envelope signal or a variable power supply voltage appropriate for average output power of the second power amplifier.

4. The amplifier circuit according to claim 3, further comprising:
a control circuit connected to the first tracker, the second tracker, the first switch, and the second switch.

5. The amplifier circuit according to claim 4,
wherein the control circuit
causes the first switch to be in a conduction state and the second switch to be in a non-conduction state assuming the variable power supply voltage of the first tracker and the variable power supply voltage of the second tracker are to be supplied to the first power amplifier,
causes the first switch to be in the non-conduction state assuming only the variable power supply voltage of the first tracker is to be supplied to the first power amplifier, and
causes the first switch to be in the non-conduction state and the second switch to be in the conduction state assuming only the variable power supply voltage of the second tracker is to be supplied to the second power amplifier.

6. The amplifier circuit according to claim 5,
wherein in a case where output current of the first tracker is Iₒᵤₜ and efficiency of the first tracker expressed as a function of the output current Iₒᵤₜ is f_{PAE}(Iₒᵤₜ),
the control circuit
causes the first switch to be in the conduction state and the second switch to be in the non-conduction state assuming f_{PAE}(Iₒᵤₜ/2)>f_{PAE}(Iₒᵤₜ) is satisfied.

7. The amplifier circuit according to claim 6, further comprising:
a first filter that is connected to an output port of the first power amplifier and that has a passband including a first band; and
a second filter that is connected to an output port of the second power amplifier and that has a passband including a second band different from the first band.

8. The amplifier circuit according to claim 2,
wherein the first power amplifier is connected to an end of the third switch,
the amplifier circuit further comprising a third power amplifier connected to the end.

9. The amplifier circuit according to claim 5,
wherein the first tracker supports an analog envelope tracking mode in which the variable power supply voltage is changed to a voltage with a continuous level, based on an envelope of a radio frequency input signal input to the first power amplifier and the second power amplifier,
wherein the second tracker supports an average power tracking mode in which the variable power supply voltage is changed to a plurality of voltages with discrete levels, based on average output power of radio frequency signals output from the first power amplifier and the second power amplifier,
wherein a first radio frequency input signal having a first channel bandwidth and a second radio frequency input signal having a second channel bandwidth wider than the first channel bandwidth are input to the first power amplifier, and
wherein the control circuit
causes the first tracker to supply the variable power supply voltage to the first power amplifier assuming the first radio frequency input signal is to be input to the first power amplifier, and
causes the second tracker to supply the variable power supply voltage to the first power amplifier assuming the second radio frequency input signal is to be input to the first power amplifier.

10. A tracker module comprising:
a first output terminal and a second output terminal;
a first tracker capable of outputting a first variable power supply voltage to the first output terminal and the second output terminal;
a second tracker capable of outputting a second variable power supply voltage to the first output terminal and the second output terminal;
a first switch connected between an output port of the first tracker and an output port of the second tracker; and
a second switch connected between the second tracker and the second output terminal.

11. The tracker module according to claim 10, further comprising:
a third switch connected between the first tracker and the first output terminal.

12. The tracker module according to claim 11, further comprising:
a control circuit connected to the first tracker, the second tracker, the first switch, and the second switch.

13. The tracker module according to claim 12,
wherein the control circuit
causes the first switch to be in a conduction state and the second switch to be in a non-conduction state assuming the first variable power supply voltage and the second variable power supply voltage are to be applied to the first output terminal,
causes the first switch to be in the non-conduction state assuming only the first variable power supply voltage is to be supplied to the first output terminal, and
causes the first switch to be in the non-conduction state and the second switch to be in the conduction state assuming only the second variable power supply voltage is to be supplied to the second output terminal.

14. An amplifying module comprising:
a first input terminal to which a first variable power supply voltage is applied and a second input terminal to which a second variable power supply voltage is applied;
a first power amplifier and a second power amplifier;
a first switch connected between the first input terminal and the second input terminal; and
a second switch connected between the second power amplifier and the second input terminal,
wherein the first power amplifier is connected to the first input terminal.

15. The amplifying module according to claim 14, further comprising:
a third switch connected between the first power amplifier and the first input terminal.

16. The amplifying module according to claim 15, further comprising:
a first filter that is connected to an output port of the first power amplifier and that has a passband including a first band; and
a second filter that is connected to an output port of the second power amplifier and that has a passband including a second band different from the first band.

17. The amplifying module according to claim 15,
wherein the first power amplifier is connected to an end of the third switch,
the amplifying module further comprising a third power amplifier connected to the end.

18. A communication device comprising:
a signal processing circuit that processes a radio frequency signal;
the tracker module according to claim 12 that is connected to the signal processing circuit; and
an amplifying module including a power amplifier that receives a variable power supply voltage from the tracker module.

19. A communication device comprising:
a signal processing circuit that processes a radio frequency signal;
the amplifying module according to claim 17 that transmits the radio frequency signal between the signal processing circuit and an antenna; and
a tracker module including a tracker that is connected to the signal processing circuit and that supplies the variable power supply voltage to the amplifying module.

20. A communication device comprising:
a signal processing circuit that processes a radio frequency signal;
the amplifying module according to claim 14 that transmits the radio frequency signal between the signal processing circuit and an antenna; and
a tracker module including a tracker that is connected to the signal processing circuit and that supplies the variable power supply voltage to the amplifying module.
